(19) United States
(12) Patent Application Publication
(10) Pub. No.: US 2011/0315222 A1
(43) Pub. Date: Dec. 29, 2011

(54) ENERGY ABSORBING LAYER FOR A PHOTOVOLTAIC DEVICE

(76) Inventor: Todd Krajewski, Mountain View, CA (US)

(21) Appl. No.: 12/824,607

(22) Filed: Jun. 28, 2010

(51) Int. Cl. H01L 31/0203; H01L 31/18

(52) U.S. Cl. 136/259; 438/64; 257/E31.117

(57) ABSTRACT

A photovoltaic device, including at least one photovoltaic cell, a flexible transparent layer formed over the at least one photovoltaic cell, a first encapsulant layer formed over a first major surface of the flexible transparent layer facing the at least one photovoltaic cell and a second encapsulant layer formed over a second major surface of the flexible transparent layer facing away from the at least one photovoltaic cell. The second encapsulant layer is made of a shear thickening polymer.

### FIELD OF THE INVENTION

Embodiments described herein relate generally to photovoltaic devices and modules, and more specifically to flexible photovoltaic devices and modules comprising protective films, layers and coatings.

### BACKGROUND OF THE INVENTION

Copper indium diselenide (CuInSe₂, or CIS) and its higher band gap variants, such as copper indium gallium diselenide (Cu(In,Ga)Se₂, or CIGS), and any of these compounds with sulfur replacing some of the selenium represent a group of materials, referred to as copper indium selenide CIS based alloys, have desirable properties for use as the absorber layer in thin-film solar cells as used in photovoltaic modules. These layers are susceptible to damage from water and/or water vapor.

Photovoltaic (“PV”) modules used in residential structures and roofing materials for generating electricity often require additional protection from environmental damage, such as an ingress of water, that can reduce an active lifetime of the photovoltaic system. Additionally, these modules require protection from hail, rocks, dropped tools or other objects that may impact their surfaces. Thick encapsulating layers or glass have been used to increase the protection to the underlying devices. However, the weight of the thicker glass adds to the shipping cost of the module, and may also limit the placement options for the module. Thicker glass also requires more material which leads to increased cost.

Rigid or flexible sheets of glass may be used to support and/or provide protection to the underlying semiconductor layers. These sheets, however, may themselves be susceptible to cracking when impacted, thereby exposing the semiconductor layers to moisture and other environmental conditions that diminish the lifetime of the cell or completely destroy it. Also, certain impacts may cause cracks that do not extend to the underlying semiconductor layers initially, but may propagate over time, for example during thermal expansion and contraction cycles resulting from change of temperature during the day, or over several months and seasons.

Additionally, flexible glasses are susceptible to weakness from micro scratches produced during processing, and/or abrasion during weathering. These micro scratches and abrasions act as stress concentrators and/or crack initiation sites which may compromise resistance to impact and/or resistance to moisture barrier properties.

Furthermore, plural impacts over a narrow radius can exceed the tensile strength of the glass and cause breakage.

### SUMMARY

One embodiment provides a photovoltaic device, including at least one photovoltaic cell, a flexible transparent layer formed over the at least one photovoltaic cell, a first encapsulant layer formed over a first major surface of the flexible transparent layer facing the at least one photovoltaic cell, and a second encapsulant layer formed over a second major surface of the flexible transparent layer facing away from the at least one photovoltaic cell. In this embodiment, the second encapsulant layer comprises a shear thickening polymer.

Another embodiment provides a method of making a photovoltaic device, including the steps of providing at least one photovoltaic cell, and forming a flexible transparent layer over the at least one photovoltaic cell. In this embodiment, the flexible transparent layer has a first encapsulant layer over a first major surface facing the at least one photovoltaic cell and a second encapsulant layer over a second major surface facing away from the at least one photovoltaic cell, and the second encapsulant layer comprises a shear thickening polymer.

Another embodiment provides a method of using a photovoltaic device, including operating, transporting or installing the photovoltaic device such that the device experiences an impact on its surface. In this embodiment the photovoltaic device includes at least one photovoltaic cell, a flexible transparent layer formed over the at least one photovoltaic cell, a first encapsulant layer formed over a first major surface of the flexible transparent layer facing the at least one photovoltaic cell, and a second encapsulant layer formed over a second major surface of the flexible transparent layer facing away from the at least one photovoltaic cell, wherein a viscosity of the second encapsulant layer increases upon the impact on its surface. In this embodiment, the second encapsulant layer comprises a shear thickening polymer.

### BRIEF DESCRIPTION OF THE DRAWINGS

FIG. 1 shows a side cross-sectional view of one embodiment of a photovoltaic device comprising a protective barrier.

FIG. 2 shows a side cross-sectional view of another embodiment of a photovoltaic device protective barrier comprising a first encapsulant layer formed over a first major surface of a flexible glass layer, and a second encapsulant layer formed over a second major surface of the flexible glass layer.

### DESCRIPTION OF THE EMBODIMENTS

As used herein, the term “module” includes an assembly of at least two, preferably more than two photovoltaic cells, such as 3-10,000 cells, for example. The photovoltaic cells of the module can be photovoltaic cells of any type. Each of the photovoltaic cells of the module can be a CIS based alloy (e.g., CIGS) type photovoltaic cell described above. Preferably, the photovoltaic cells of the module are thin film photovoltaic cells. The thin film photovoltaic cells of the module can be located adjacent to each other such that an interconnect provides electrical connection between them. An exemplary interconnect is described in U.S. patent application Ser. No. 11/451,616 filed on Jun. 13, 2006 and incorporated herein by reference in its entirety.

As used herein, a “shear thickening material” includes polymer materials that exhibit dilatant behavior, which viscously flow at low rates of deformation but, at an elevated rate of deformation, undergoes a substantial change in viscosity, for example an increase in viscosity, with rate of change of deformation. In other words, upon impact in a given area of shear thickening material, the material's viscosity in the impact area increases by at least 50%. For example, the shear thickening polymers include silicone polymers, such as borated silicone polymers. Examples of shear thickening materials and their properties are disclosed in U.S. Pat. No. 7,381,460 which is incorporated herein by reference in its entirety.

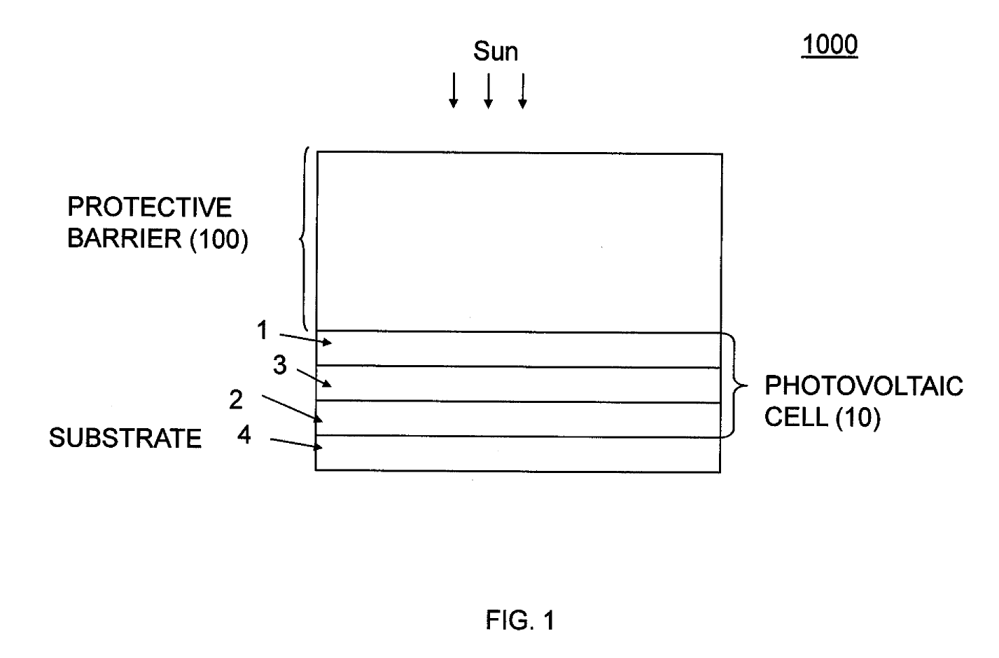

FIG. 1 illustrates a photovoltaic device 1000. The photovoltaic device 1000 in FIG. 1 includes: a) a photovoltaic cell 10 that includes a first transparent electrode 1 adapted to face the Sun, a second electrode 2 adapted to face away from the Sun and a photovoltaic material 3 disposed between the first and the second electrodes, and b) a transparent protective barrier 100. Electrode 1 may comprise a transparent conductive metal oxide, such as indium tin oxide, zinc oxide, aluminum zinc oxide or a combination thereof. Electrode 2 may comprise a metal or metal alloy, such as molybdenum or alloys thereof. The photovoltaic material 3 may include a semiconductor p-n or p-i-n junction, such as a p-CIGS absorber and n-CdS layers. The photovoltaic device 1000 may include a substrate 4. In some cases, the substrate 4 can comprise a foil or plate 4 on which an electrode 2 is disposed. In some other cases, the electrode 2 material can be eliminated and the substrate 4 can comprise a conductive plate or foil 4, such as a steel foil, which acts as the second electrode of the cell. Substrate 4 can be a flexible substrate and photovoltaic cell 10 can be a flexible photovoltaic cell which can be rolled up into a roll without breaking or becoming inoperative.

The transparent protective barrier 100 is disposed over the photovoltaic cell 10 to provide environmental protection and impact protection to the cell. When the photovoltaic cell is part of a photovoltaic module, the protective barrier can be formed continuously over other photovoltaic cells in the module. The transparent protective barrier 100 preferably comprises a thin, coated flexible glass layer. In some cases, the protective barrier 100 can be a self-supporting, i.e., a free standing glass layer. The self-supporting layer can be in a form of a roll, ribbon, web, foil or a sheet. Any suitable glass material may be used for the glass layer, such as soda lime glass, borosilicate glass, low alkali soda lime glass, etc. The glass layer may be sufficiently thin, such as having a thickness of 50-500 μm, to provide flexibility to the glass layer (e.g., so that the glass layer may be rolled up into a roll).

The protective barrier 100 can include one or more transparent sublayers (not shown in FIG. 1). The term “transparent” includes layers and materials which allow at least 75% of visible solar radiation, such as 80-100% of wavelengths of 400 nm to 1100 nm, to be transmitted to the cell(s). In some cases, the transparent protective barrier can also include a weatherable top sheet or layer (not shown in FIG. 1) on the Sun facing side of the barrier, for protecting the cell(s) from moisture. The top sheet or layer may be a flouorpolymer layer, such as a ETFE or FEP weatherable top layer.

The photovoltaic device in FIG. 1 can be encapsulated with one or more encapsulating layers (not shown in FIG. 1) between the cell 10 and barrier 100 and below the cell 10. The photovoltaic device 1000 can be formed on a structure, such as a building roof, etc., with the protective barrier 100 formed on the Sun facing side of the photovoltaic cell 10. As noted above, the barrier 100 and cell 10 may be flexible, such that the device 1000 may be rolled up into a roll without breaking or becoming inoperative. Alternatively, the device 1000 may be semi-rigid, meaning that it can be bent without breaking but cannot be rolled up into a roll. The photovoltaic device 1000 can manufactured into a roll, then be transported to its installation location (also known as “the field”), be unrolled from the roll and installed over the structure at the installation location.

Shear Thickening Polymer.

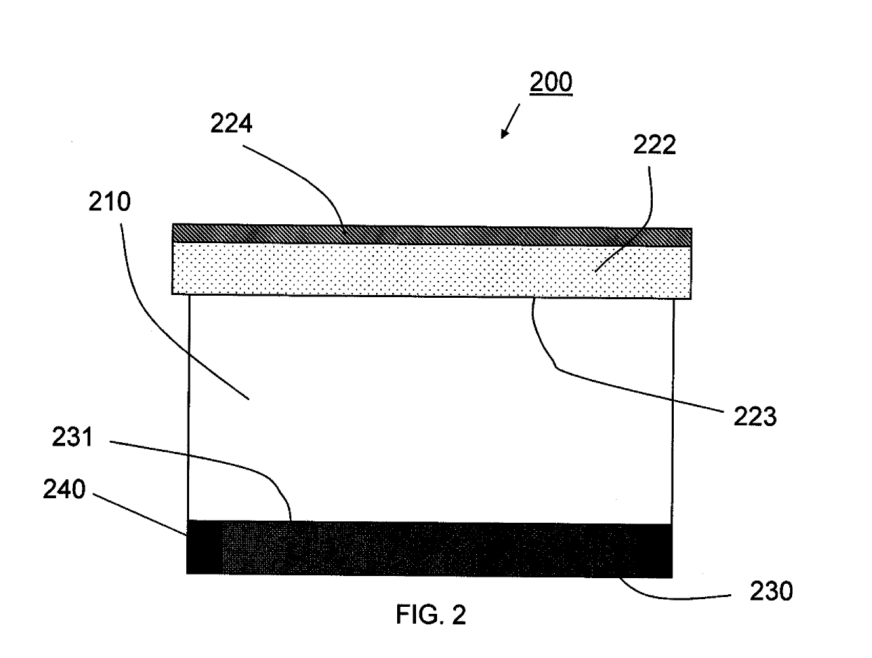

FIG. 2 illustrates an embodiment 200 of a protective barrier 100 comprising at least one shear thickening polymer layer that can be formed on or over at least one photovoltaic cell such as the photovoltaic cell 10 in FIG. 1. The protective barrier 200 can comprise a flexible layer 210, such as a flexible glass layer, formed over the at least one photovoltaic cell, for example, the at least one photovoltaic cell 10 of FIG. 1. The flexible transparent layer 210 can be a glass layer having at least 80% transmittance for wavelengths of 400 nm to 1100 nm and can have a thickness of 0.05 to 3 mm, such as 50 to 500 μm.

The flexible glass layer 210 can have a first major surface 231 facing the at least one photovoltaic cell and a second major surface 223 facing away from the at least one photovoltaic cell (e.g., toward the Sun). Additionally, the photovoltaic cell 10 can comprise a flexible photovoltaic cell formed on a flexible substrate.

The protective barrier 200 may include one or more transparent sublayers, for example a first encapsulant layer 230, a second shear thickening encapsulant layer 222, and an optional weather barrier 224.

The first encapsulant layer 230 can be formed over the first major surface 231 of the flexible glass layer 210. The first encapsulant layer 230 can comprise a shear thickening polymer or a material other than a shear thickening polymer. The material other than a shear thickening polymer can have a modulus of greater than about 500 MPa at room temperature, between about 100 MPa and 500 MPa at room temperature, or less than about 100 MPa at room temperature, such as 2-50 MPa. For example, the first encapsulant layer 230 can comprise a polymer or glass layer having a modulus of less than 50 MPa at room temperature.

The second encapsulant layer 222 can be formed over the second major surface 223 of the flexible glass layer 210, and can comprise a shear thickening polymer, such as a thermoplastic or thermoset polymer. Shear thickening polymers include silicone polymers, such as borated silicone polymers, such as polyborodimethylsiloxane (PBDMS). In one embodiment, the entire layer 222 may consist essentially of only the shear thickening polymer. In another embodiment, the second encapsulant layer 222 comprises a blend comprising the shear thickening polymer and at least one non-shear thickening polymer material. For example, the shear thickening polymer of the blend may comprise PBDMS and the non-shear thickening polymer of the blend may comprise any suitable polymer used in PV module encapsulation, such as Z68 LLDPE encapsulant, SentryGlas® hard glass polymer (architectural safety glass interlayer made by DuPont), Surlyn® resin (thermoplastic random copolymer poly(ethylene-co-methacrylic acid) (EMAA) where incorporation of methacrylic acid is typically low (<15 mol. %), made by DuPont), Tectosil® silicone based polymer encapsulant for PV modules (made by Wacker Silicones), etc. If desired, the shear thickening polymer may be a reversible shear thickening polymer whose viscosity increases upon impact but then decreases again after the impact. Examples of such polymers include silicone sealants, such as dimethyl, methylhydrogen siloxane containing sealants, including Dow Corning 1700 series sealants.

The dilatant material experiences a substantial increase in viscosity proportional to the rate of deformation during impact. In a non-limiting example the second encapsulant layer 222 is capable of experiencing a change in modulus from below 500 MPa to above 750 MPa at room temperature upon impact having a force of at least 3 Joules on its surface, and/or at least a 50% increase in viscosity at room temperature upon the impact on its surface. In other words, the second encapsulant layer 222 experiences a change from a relatively flexible state to a relatively rigid state upon impact on its surface. This behavior spreads the force of the impact as well as prevents or reduces deformation of the glass layer 210, the PV cells and/or other module components.

The optional weather barrier 224 can be a fluorinated polymer weather barrier (e.g., water and/or oxygen barrier) formed over the second encapsulant layer 222. Examples of the weather barrier 224 comprise weatherable polymers, such as ETFE, FEP, CTFE, etc., or one or more layers of other organic or inorganic, flexible barrier materials formed by atomic layer deposition, sol-gel deposition, etc.

Optionally, the flexible transparent glass layer 210 has one or more additional inorganic, organic, or organic-inorganic hybrid protective layers over the surface 223 of the glass layer that faces the Sun either above or below the shear thickening polymer containing encapsulating layer 222. The optional protective layer(s) may provide one or more of the following advantages: they may fill any existing microcracks and/or prevent formation of new ones, they may prevent water contact and interaction with the glass layer surface or with any defects on the glass layer surface, and/or they may decrease the impulse of impacts and/or increase the impact area when an object (e.g., hail, rocks, tree branches, dropped tools, etc.) impacts the barrier 100.

A method of using the photovoltaic device 1000 shown in FIG. 1 comprises the steps of operating, transporting and/or installing the photovoltaic device such that the device experiences an impact on its surface (e.g., impact from objects such as hail, rocks, or tree branches, tools, moving equipment, etc.). The photovoltaic device 1000 can comprise the photovoltaic cell 10, the flexible transparent glass layer 210 formed over the at least one photovoltaic cell, for example a Sun facing surface of the at least on photovoltaic cell. A first encapsulant layer 230 can be formed over a first major surface 231 of the flexible transparent layer facing the at least one photovoltaic cell, and a second encapsulant layer 222 can be formed over a second major surface 223 of the flexible transparent layer facing away from the at least one photovoltaic cell. As described above, the second encapsulant layer 222 can comprise a shear thickening polymer. A viscosity of the second encapsulant layer 222 can increases upon the impact on its surface.

It is to be understood that the present invention is not limited to the embodiments and the examples described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells described herein.

What is claimed is:

1. A photovoltaic device, comprising:
at least one photovoltaic cell;
a flexible transparent layer formed over the at least one photovoltaic cell;
a first encapsulant layer formed over a first major surface of the flexible transparent layer facing the at least one photovoltaic cell; and
a second encapsulant layer formed over a second major surface of the flexible transparent layer facing away from the at least one photovoltaic cell, the second encapsulant layer comprises a shear thickening polymer.

2. The photovoltaic device of claim 1, wherein the flexible transparent layer is a glass layer having at least 80% transmittance for wavelengths of 400 nm to 1100 nm and a thickness of 50 to 500 μm.

3. The photovoltaic device of claim 1, wherein the second encapsulant layer comprises a blend comprising the shear thickening polymer and a non-shear thickening polymer material.

4. The photovoltaic device of claim 3, wherein the shear thickening polymer comprises polyborodimethylsiloxane.

5. The photovoltaic device of claim 1, wherein the shear thickening polymer comprises a thermoplastic or thermoset polymer.

6. The photovoltaic device of claim 1, wherein the shear thickening polymer is a reversible shear thickening polymer.

7. The photovoltaic device of claim 1, wherein the second encapsulant layer is capable of experiencing a change in modulus from below 500 MPa to above 750 MPa at room temperature upon impact on its surface.

8. The photovoltaic device of claim 1, wherein the shear thickening polymer is capable of experiencing at least a 50% increase in viscosity at room temperature upon impact on its surface.

9. The photovoltaic device of claim 1, wherein the second encapsulant layer experiences a change from a flexible state to a rigid state upon impact on its surface.

10. The photovoltaic device of claim 1, wherein the first encapsulant layer comprises a shear thickening polymer.

11. The photovoltaic device of claim 1, wherein the at least one photovoltaic cell is formed on a flexible substrate and the photovoltaic device is flexible and can be rolled up in a roll.

12. The photovoltaic device of claim 1, further comprising a fluorinated polymer weather barrier formed over the second encapsulant layer.

13. A method of making a photovoltaic device, comprising:
providing at least one photovoltaic cell; and
forming a flexible transparent layer over the at least one photovoltaic cell;
wherein the flexible transparent layer has a first encapsulant layer over a first major surface facing the at least one photovoltaic cell and a second encapsulant layer over a second major surface facing away from the at least one photovoltaic cell, and the second encapsulant layer comprises a shear thickening polymer.

14. The method of claim 13, wherein the flexible transparent layer comprises a glass layer having at least 80% transmittance for wavelengths of 400 nm to 1100 nm and a thickness of 50 to 500 μm.

15. The method of claim 13, wherein the second encapsulant layer comprises a blend comprising the shear thickening polymer and a non-shear thickening polymer material.

16. The method of claim 15, wherein the shear thickening polymer comprises polyborodimethylsiloxane.

17. The method claim 13, wherein the shear thickening polymer comprises a thermoplastic or thermoset polymer.

18. The method claim 13, wherein the shear thickening polymer is a reversible shear thickening polymer.

19. The method of claim 13, wherein the second encapsulant layer is capable of experiencing a change in modulus from below 500 MPa to above 750 MPa at room temperature upon impact on its surface.

20. The method of claim 13, wherein the shear thickening polymer is capable of experiencing at least a 50% change in viscosity at room temperature upon impact on its surface.

21. The method of claim 13, wherein the second encapsulant layer experiences a change from a flexible state to a rigid state upon impact on its surface.

22. The method of claim 13, wherein the first encapsulant layer comprises a shear thickening polymer.

23. The method of claim 13, wherein the at least one photovoltaic cell is formed on a flexible substrate and the photovoltaic device is flexible and can be rolled up in a roll.

24. The method of claim 13, further comprising a fluorinated polymer weather barrier formed over the first encapsulant layer.

25. A method of using a photovoltaic device, comprising:
operating, transporting or installing the photovoltaic device such that the device experiences an impact on its surface, the photovoltaic device comprising:
at least one photovoltaic cell;
a flexible transparent layer formed over the at least one photovoltaic cell;
a first encapsulant layer formed over a first major surface of the flexible transparent layer facing the at least one photovoltaic cell; and
a second encapsulant layer formed over a second major surface of the flexible transparent layer facing away from the at least one photovoltaic cell, the second encapsulant layer comprises a shear thickening polymer;
wherein a viscosity of the second encapsulant layer increases upon the impact on its surface.

26. The method of claim 25, wherein:
the flexible transparent layer comprises a glass layer having at least 80% transmittance for wavelengths of 400 nm to 1100 nm and a thickness of 50 to 500 μm; and
the viscosity of the shear thickening polymer increases by at least 50% upon the impact to spread a force of the impact and to at least one of reduce and prevent deformation of the flexible transparent layer and the at least one photovoltaic device.
